(19) United States
(12) Patent Application Publication
(10) Pub. No.: US 2007/0235882 A1
(43) Pub. Date: Oct. 11, 2007

(54) Semiconductor device and method for fabricating the same

(75) Inventors: Masahiro Sekiguchi, Yokohama-shi (JP); Kenji Takahashi, Tsukuba-shi (JP); Hideo Numata, Yokohama-shi (JP); Tatsuhiko Shirakawa, Tokyo (JP); Ninao Sato, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/783,369

(22) Filed: Apr. 9, 2007

(30) Foreign Application Priority Data
Apr. 10, 2006 (JP) P2006-107249
Sep. 29, 2006 (JP) P2006-268342

(51) Int. Cl. H01L 23/52

(52) U.S. Cl. 257/777

(57) ABSTRACT

A semiconductor device includes a semiconductor substrate with an electrode pad on a main surface of the semiconductor substrate; a first penetrating electrode which includes a through hole formed through the semiconductor substrate in the thickness direction so as to reach a metallic bump formed on the electrode pad, an insulating resin formed to fill the through hole in and a conductor formed in the through hole with insulated from the semiconductor substrate by the insulating resin and electrically to connect the electrode pad and the rear surface of the semiconductor wafer; a semiconductor chip mounted on the rear surface of the semiconductor wafer so that a rear surface of the semiconductor chip is faced to the rear surface of the semiconductor wafer; and a wiring to electrically connect the first penetrating electrode and an electrode formed on the semiconductor chip.

### CROSS-REFERENCE TO RELATED APPLICATIONS

This application is based upon and claims the benefit of priority from the prior Japanese Patent Application No. 2006-107249 filed on Apr. 10, 2006 and the prior Japanese Patent Application No. 2006-268342 filed on Sep. 29, 2006; the entire contents which are incorporated herein by reference.

### BACKGROUND

1. Field of the Invention

The present invention relates to a semiconductor device and a method for fabricating the semiconductor device, particularly a semiconductor device with a penetrating electrode and a method for fabricating the same semiconductor device.

2. Description of the Related Art

In various instruments containing semiconductor devices, that is, small-sized mobile instruments such as future cellular phones and digital cameras which are promised to be commercially developed in the future, the miniaturization and multiple function for the mobile instruments are more developed and the high density packaging technique for the mobile instruments is required as the number of chip to be mounted is increased originated from the high performance and high leveled function of the mobile instruments. In order to realize the above-mentioned requirements, the high density SiP (System in Package) of stacked MCP type is being developed at present, and then, in order to realize the remarkable downsize (thinning) of the mobile instruments, the CoC (Chip on Chip) technique to connect a chip directly with another chip is being investigated. In the CoC technique, it is known that a through plug is employed (refer to Documents No. 1 and No. 2). FIG. 7 is a structural view showing a penetrating electrode. As shown in FIG. 7, a through hole 54 is formed so as to penetrate from the semiconductor element surface (main surface) 52 to the rear surface 53 of the semiconductor substrate 51 constituting a semiconductor chip, and a conductor 56 is filled in the through hole 54 with insulated from the inner wall of the through hole 54 by a SiO₂ film 55, thereby forming a penetrating electrode 57. In FIG. 7, the reference numeral “58”, designates an electrode pad and the reference numeral “59” designates a passivation film.

[Document No. 1] Japanese Patent Laid-open Application No. 10-223833

[Document No. 2] Japanese Patent No. 3186941

In the formation of the penetrating electrode using the above-mentioned technique, since a semiconductor pre-fabricating technique (RIE, CVD, CMP etc.) is employed, a high degree technique in the fabricating process is required so that the fabricating cost is also increased.

### SUMMARY

An aspect of the present invention relates to a semiconductor device comprises: a semiconductor substrate with an electrode pad on a main surface of the semiconductor substrate; a first penetrating electrode which includes a through hole formed through the semiconductor substrate in the thickness direction from a rear surface to the main surface in the semiconductor substrate so as to reach a metallic bump formed on the electrode pad, an insulating resin formed so as to fill the through hole in and a conductor formed in the through hole with insulated from the semiconductor substrate by the insulating resin and electrically to connect the electrode pad and the rear surface of the semiconductor wafer; a semiconductor chip mounted on the rear surface of the semiconductor wafer so that a rear surface of the semiconductor chip is faced to the rear surface of the semiconductor wafer; and a wiring to electrically connect the first penetrating electrode and an electrode formed on the semiconductor chip.

Another aspect of the present invention relates to a semiconductor device comprises: a semiconductor substrate with an electrode pad on a main surface of the semiconductor substrate; and a penetrating electrode which includes a through hole formed through the semiconductor substrate in the thickness direction from a rear surface to the main surface in the semiconductor substrate so as to reach a metallic bump formed on the electrode pad, an insulating resin formed so as to fill the through hole in and a conductor formed in the through hole with insulated from the semiconductor substrate by the insulating resin and electrically to connect the electrode pad and the rear surface of the semiconductor wafer.

Still another aspect of the present invention relates to a method for fabricating a semiconductor device comprises: forming a first through hole at a semiconductor substrate with an electrode pad on a main surface of the semiconductor substrate through the semiconductor substrate in the thickness direction from a rear surface to the main surface of the semiconductor substrate so as to reach a metallic bump formed on the electrode pad; filling an insulating resin into the first through hole from the rear surface of the semiconductor wafer; forming a second through hole in the insulating resin from the rear surface of the semiconductor wafer so as to reach a metallic bump formed on the electrode pad under the condition that a diameter of the second through hole is set smaller than a diameter of the first through hole; forming, in the second through hole, a first penetrating electrode made of a conductor which is formed over the rear surface of the semiconductor wafer so as to be electrically contacted with the electrode pad; mounting a semiconductor chip on the rear surface of the semiconductor wafer so that a rear surface of the semiconductor chip is faced to the rear surface of the semiconductor wafer; and forming a wiring to electrically connect the first penetrating electrode and an electrode formed on the semiconductor chip.

A further aspect of the present invention relates to a method for fabricating a semiconductor device comprises: forming a first through hole at a semiconductor substrate with an electrode pad on a main surface of the semiconductor substrate through the semiconductor substrate in the thickness direction from a rear surface to the main surface of the semiconductor substrate so as to reach a metallic bump formed on the electrode pad; filling an insulating resin into the through hole from the rear surface of said semiconductor wafer; forming a second through hole in the insulating resin from the rear surface of the semiconductor wafer so as to reach a metallic bump formed on the electrode pad under the condition that a diameter of the second through hole is set smaller than a diameter of the first through hole; and forming, in the second through hole, a penetrating electrode made of a conductor which is formed over the rear surface of the semiconductor wafer so as to be electrically contacted with the electrode pad.

### BRIEF DESCRIPTION OF THE DRAWINGS

FIG. 1 is a structural view showing a semiconductor device according to one embodiment.

FIG. 2 relates to cross sectional views showing the fabricating steps for the semiconductor device in FIG. 1.

FIG. 3 relates to cross sectional views showing the subsequent fabricating steps after the fabricating steps in FIG. 2.

FIG. 4 is a structural view showing another semiconductor device according to another embodiment.

FIG. 5 is a structural view showing the semiconductor device entirely in FIG. 4.

FIG. 6 relates to cross sectional views showing the fabricating steps of the penetrating electrode.

FIG. 7 is an explanatory view for the penetrating electrode.

### DETAILED DESCRIPTION

Hereinafter, embodiments of the present invention will be described with reference to the drawings. The drawings, though referred to in describing the embodiments of the present invention, are provided only for an illustrative purpose and in no way limit the present invention.

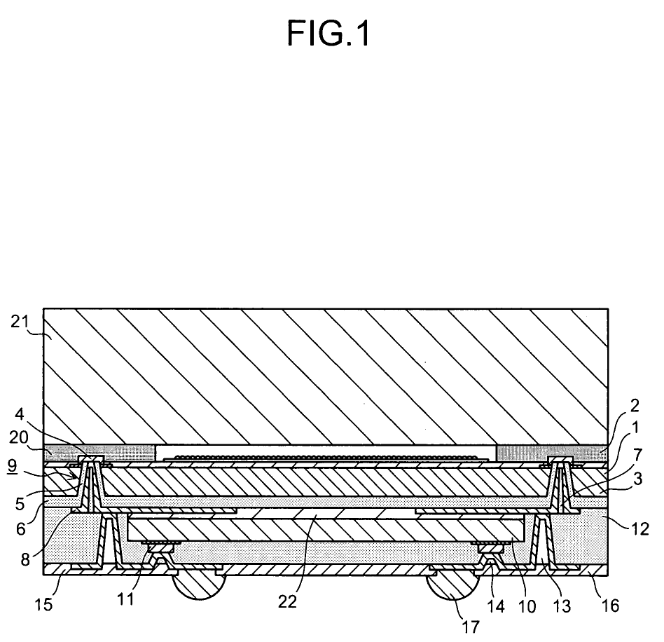

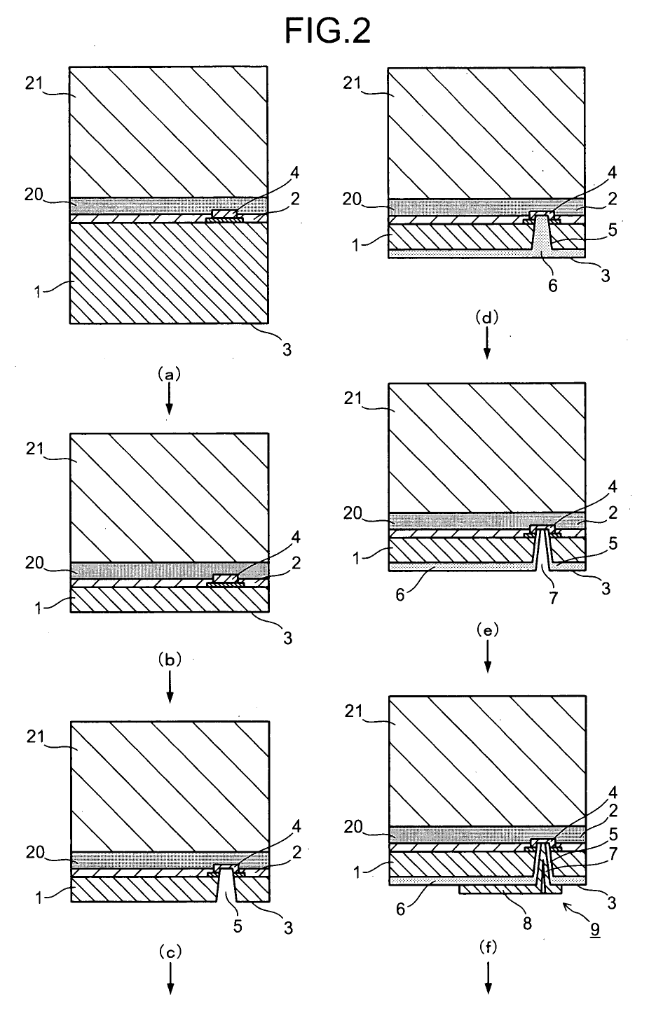

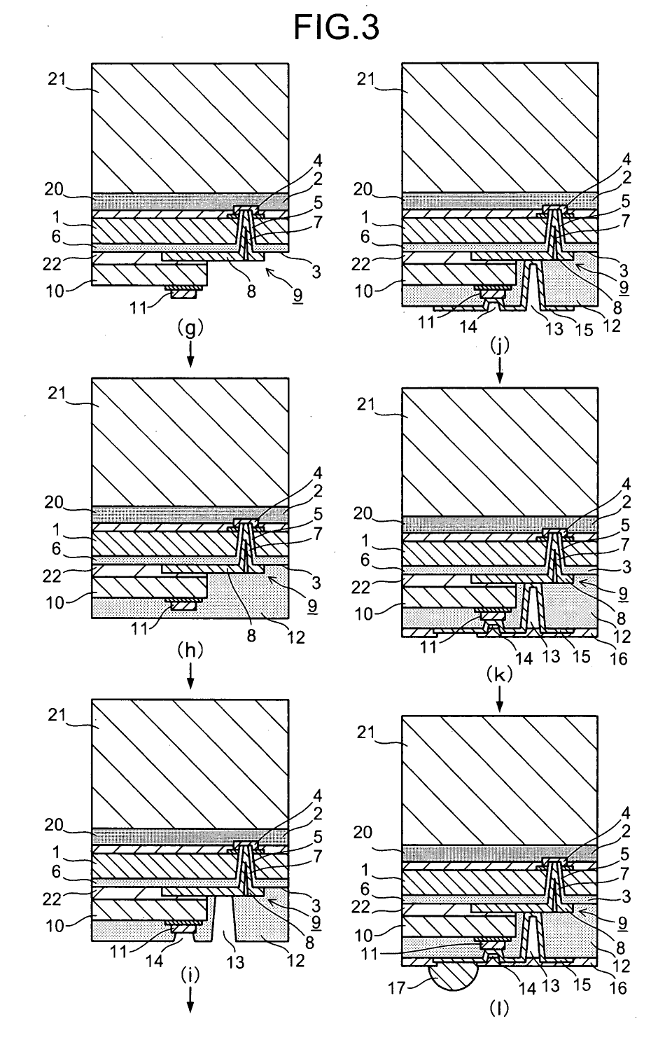

FIG. 1 is a structural view schematically showing a semiconductor device according to one embodiment, and FIGS. 2 and 3 relates to cross sectional views showing the fabricating steps for the semiconductor device in FIG. 1. First of all, a method for fabricating the semiconductor device in this embodiment will described in view of FIGS. 2 and 3.

In FIG. 2(a), the reference numeral “1” designates a semiconductor wafer, and a supporting plate 21 is adhered onto the main surface 2 (the surface on which the semiconductor circuit element is formed) with adhesive agent. The supporting plate 21 may remain the same so as to constitute the desired semiconductor package or be peel off from the semiconductor wafer 1 after the completion. In FIG. 2(a), the reference numeral “3” designates a rear surface of the semiconductor wafer 1, and the reference numeral “4” designates a metallic bump formed on the electrode pad on the semiconductor wafer 1. As described below, the metallic bump 4 functions as a stopper against laser processing and thus, is made of Ni, Au, Cu syndicate treated and the like. In order to realize the sufficient stopper against the laser processing, it is desired that the thickness of the metallic bump 4 is set several times as large as the electrode pad of the semiconductor wafer 1 (generally set within several hundreds nm to 2 μm), e.g., within 3 to 20 μm. However, an etching process (wet etching or RIE) may be utilized instead of the laser processing

Then, the rear surface 3 of the semiconductor wafer 1 adhered with the supporting plate 21 is grinded to a prescribed thickness by means of BSG process, that is, by grinding the rear surface 3 through the adhesion of a supporting tape to the semiconductor wafer 1. In this case, in order to increase the deflecting strength of the semiconductor wafer 1, the rear surface 3 may be dry-polished as occasion demands (FIG. 2(b)).

Then, a through hole (first through hole) 5 is formed so as to penetrate the electrode pad from the rear surface 3 of the semiconductor wafer 1 in the thickness direction and reduce the metallic bump 4 by irradiating a laser beam to the rear surface 3 of the semiconductor wafer 1 (FIG. 2(c)). In this case, the metallic bump 4 functions as the stopper against the laser processing.

In this way, since the metallic bump 4 is utilized as the stopper against the laser processing so that the through hole 5 is formed so as to penetrate the electrode pad from the rear surface 3 of the semiconductor wafer 1 in the thickness direction and reduce the metallic bump 4, the through hole 5 can be formed surely at the semiconductor wafer 1 from the rear surface 3 of the semiconductor wafer 1 to the metallic bump 4, not throughout the metallic bump 4. If the metallic bump 4 is not utilized, the through hole 5 is formed too deep so as to penetrate the electrode pad or too shallow to reach the electrode pad by the laser processing. In order to form the through hole 5 so as to penetrate only the semiconductor wafer 1 in the thickness direction, in this point of view, a high processing accuracy is required so that the productivity yield may be lowered. In contrast, the use of the metallic bump 4 as the stopper against the laser processing can form the desired through hole without the high processing accuracy at the high productivity yield.

After the through hole is formed by means of the laser processing, the washing step may be prepared as occasion demands. Then, before the through hole is formed by means of the laser processing, the formation step of protective film on the rear surface 3 may be prepared. The protective film is formed against the debris scattering originated from the laser processing. The protective film may be removed after the formation of the through hole. The laser processing can be conducted under-good condition by means of YAG laser with a wavelength of 355 nm, but any kind of laser may be employed.

Then, an epoxy-based insulating resin film is laminated on the rear surface 3 of the semiconductor wafer 1 so that an insulating resin 6 can be filled into the through hole 5 and cover the rear surface 3 of the semiconductor wafer 1 (FIG. 2(d)). In this process, the lamination can be conducted by means of vacuum condition lamination or roll-coating lamination. In order to insulate the silicon inner wall of the through hole 5 from a conductor 8 as described below, it is required to cover the inner wall of the through hole 5 entirely with the insulating resin 6 so as to reach the metallic bump 4. The use of the exemplified means such as vacuum lamination or roll-coating lamination can fill the through hole 5 in with the insulating resin 6 easily.

Then, a through hole (second through hole) 7 is formed in the insulating resin 6 filled in the through hole 5 so as to penetrate the electrode pad and reach the metallic bump 4 by means of laser processing or the like. The diameter of the through hole 7 is set smaller than the diameter of the through hole 5. In this way, the insulating resin 6 results in being formed on the inner silicon wall of the through hole 5 (FIG. 2(e)). In this case, since the insulating resin 6 is processed by means of laser, a CO₂ laser may be employed in the laser processing, but a YAG laser may be employed. However, an etching process (wet etching or RIE) may be utilized instead of the laser processing

Then, the conductor 8 is formed on the rear surface 3 of the semiconductor wafer 1 and the side wall, the bottom of the through hole 7 by means of electroless plating or the like. The conductor 8 is patterned by means of etching via a mask, thereby forming the wiring of the conductor 8 (FIG. 2(f)). The conductor 8 may be formed by means of deposition or sputtering, instead of the electroless plating. In this case, the conductor 8 can be formed under good condition. The conductor 8 is made of Ti, Ni, Cu, V, Cr, Pt, Pd, Au, Sn in accordance with the intention of the conductor 8. The conductor 8 may be formed by means of electrolytic plating using a conductor made by the electroless plating as an electrode. In this way, an intended penetrating electrode 9 is formed through the semiconductor wafer 1 to the main surface from the rear surface.

The subsequent processing steps will be described in view of FIG. 3. A semiconductor chip 10 is mounted on the rear surface 3 of the semiconductor wafer 1 via the insulating resin 6 and an adhesive agent 22 so that the rear surface of the semiconductor chip 10 is faced to the rear surface 3 of the semiconductor wafer 1 (FIG. 3(g)). Then, the electrode 11 of the semiconductor chip 10 may be wire-bonded with the conductor 8 formed on the rear surface 3 of the semiconductor wafer 1.

Then, an insulating resin film is laminated on the semiconductor assembly shown in FIG. 3(g) from the surface thereof on which the semiconductor chip 10 is mounted to form an insulating resin layer 12 (FIG. 3(h)). The insulating resin layer 12 may be made of a material different from the material of the insulating resin 6.

Then, a through hole (third through hole) 13 to reach the conductor 8 on the rear surface 3 of the semiconductor wafer 1 and a through hole (fourth through hole) 14 to reach the electrode 11 of the semiconductor chip 10 are formed in the insulating resin layer 12 by means of laser processing or the like (FIG. 3(i)). This formation process can be conducted in the same manner as the formation process of the through hole 7 in the insulating resin 6. The through hole 13 may be formed at the position of the penetrating electrode 9. However, an etching process (wet etching or RIE) may be utilized instead of the laser processing.

Then, a conductor 15 is formed on the insulating resin layer 12 and the side walls, the bottoms of the through holes 13, 14 (FIG. 3(j)). In this case, when it is required that the semiconductor wafer 1 is electrically connected with the semiconductor chip 10, the electrode 11 of the semiconductor chip 10 can be wired with the electrode 4 of the semiconductor wafer 1 via the penetrating electrode 9.

Then, in view of the reliability of the semiconductor assembly, a protective film 16 may be coated or applied on the wiring surface of the conductor 15, and an opening is formed at the protective film 16 through exposure and development (FIG. 3(k)), and an outside electrode 17 is formed at the opening of the protective film 16 as occasion demands. Herein, the protective film 16 may be made of a liquid material or filmy material. The liquid material is coated and the filmy material is applied. If the surface of the semiconductor assembly is required to be flattened in the formation of the coating or application of the protective film 16, the through holes 13 and 14 may be filled in the resin of the protective film 16 or a given resin in advance. Since the opening of the protective film 16 is utilized for the formation of the outside electrode 17, the opening can be formed at the position of the through hole 13 or 14, or another position except the through holes 13 and 14. The outside electrode 17 may be formed as a solder ball and thus, may be made of Au, Ni/Au by means of electroless plating. The outside electrode 17 may be treated in rust prevention.

The semiconductor device shown in FIG. 1 is fabricated through the steps shown in FIGS. 2 and 3. Like or corresponding components are designated by the same reference numerals through FIGS. 1 to 3. Herein, since the semiconductor wafer 1 is cut off into semiconductor devices after the semiconductor assembly is fabricated in accordance with the steps shown in FIGS. 2 and 3, in FIG. 1, the semiconductor wafer 1 means a semiconductor wafer cut off of the inherent semiconductor wafer.

In FIG. 1, the semiconductor device includes the penetrating electrode 9 which is formed through the formation of the through hole 5 in the semiconductor wafer 1 by means of the laser processing, the filling of the insulating resin 6 into the through hole 5 by means of the lamination of the insulating resin film, the formation of the through hole 7 in the insulating resin 6 and the formation of the conductor 8 by means of the electroless plating.

Namely, the semiconductor device includes the penetrating electrode 9 which includes the through hole 5 formed through the semiconductor substrate 1 in the thickness direction from the rear surface 3 of the main surface 2 thereof so as to reach the metallic bump 4 formed on the electrode pad, the insulating resin 6 formed so as to fill the through hole 5 in and the conductor 8 formed in the through hole 5 with insulated from the semiconductor substrate by the insulating resin 6 and electrically to connect the electrode pad and the rear surface of the semiconductor wafer 1.

Therefore, the fabricating process of semiconductor device can be simplified in comparison with a conventional one, and thus, the fabricating cost of semiconductor device can be reduced. The conductor 8 may be made by an insulating resin film with a copper foil on the one side thereof, but according to this embodiment, the conductor 8 can be more thinned so as to render the wiring pattern finer.

In this embodiment, the one semiconductor chip 10 is mounted on the semiconductor wafer 1, but a plurality of semiconductor chips may be mounted by repeating the steps shown in FIGS. 3(g) to 3(j) after the step in FIG. 3(j). In this embodiment, the semiconductor chip 10 is mounted on the semiconductor wafer 1, but it is required to form no through hole in the Si substrate of the semiconductor chip 10 to be mounted on the semiconductor wafer 1. Since the formation of the through hole in the insulating resin can be simplified than the formation of the through hole in the Si substrate, the fabricating process of semiconductor device according to this embodiment can be simplified and the fabricating cost of semiconductor device according to this embodiment can be reduced in comparison with the conventional ones relating to the formation of the through hole in the Si substrate.

In this embodiment relating to FIGS. 1 to 3, the one semiconductor chip 10 is mounted in the one semiconductor device, but a plurality of semiconductor chips may be mounted in the one semiconductor device.

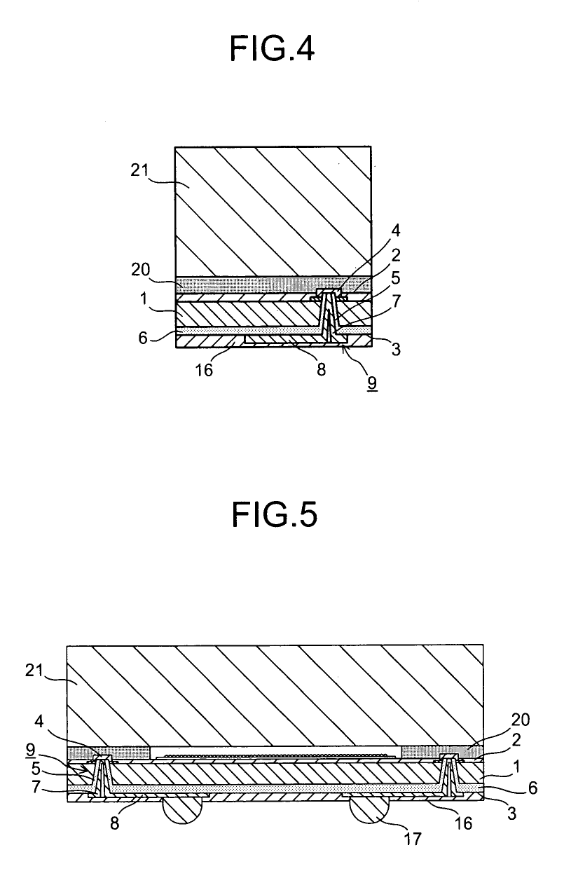

Then, another embodiment will be described in view of FIG. 4. FIG. 4 is a structural view schematically showing another semiconductor device according to another embodiment. The semiconductor device can be fabricated through the formation of the penetrating electrode 9 in the semiconductor wafer 1 in accordance with the steps shown in FIGS. 2(a) to 2(f) and the formation of the protective film 16 in accordance with the step shown in FIG. 3(k) without the mounting of the semiconductor chip. FIG. 5 is a structural view showing the resultant semiconductor device. Like or corresponding components are designated by the same reference numerals throughout FIGS. 4 and 5. As shown in FIG. 5, in this embodiment, the semiconductor chip 10 is not mounted and the outside electrode 17, which is electrically connected with the conductor 8, is formed at the opening of the protective film 16.

In this embodiment, since the semiconductor device includes the penetrating electrode 9 which is formed through the formation of the through hole 5 in the semiconductor wafer 1 by means of the laser processing, the filling of the insulating resin 6 into the through hole 5 by means of the lamination of the insulating resin film, the formation of the through hole 7 in the insulating resin 6 and the formation of the conductor 8 by means of the electroless plating, the fabricating process of semiconductor device can be simplified and the fabricating cost of semiconductor device can be reduced.

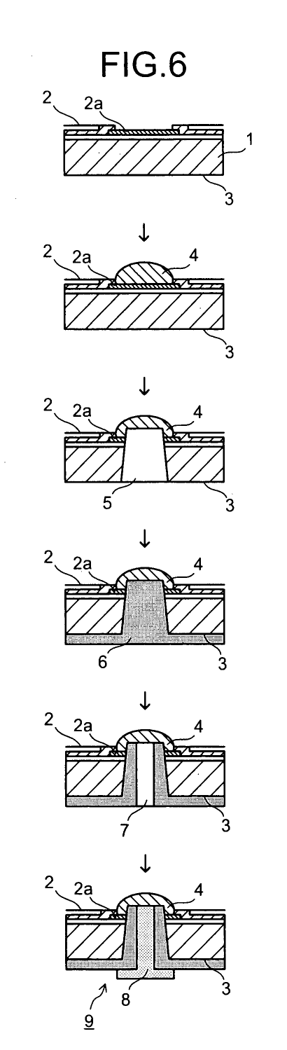

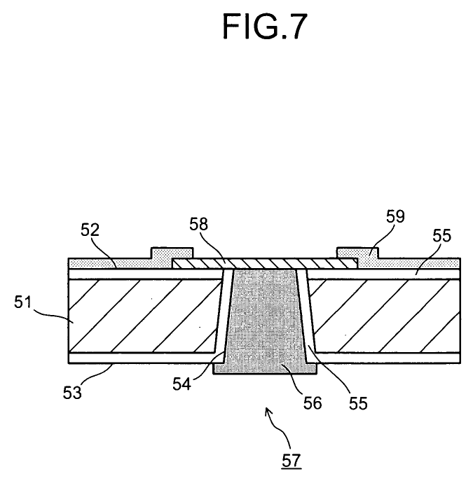

FIG. 6 relates to enlarged cross sectional views showing the fabricating steps of the penetrating electrode 9. In FIG. 2(a), the reference numeral “1” designates a semiconductor wafer, and the reference numeral “2” designates a main surface (a surface on which a semiconductor circuit element is formed) of the semiconductor wafer 1, and the reference numeral “3” designates a rear surface of the semiconductor wafer 1. An electrode pad 2a is formed on the main surface 2 of the semiconductor wafer 1. As shown in FIG. 6(b), a metallic bump 4 is formed on the electrode pad 2a (of Ni, Au, Cu syndicate treated and the like in a thickness of about 3 to 20 μm).

Then, as shown in FIG. 6(c), a through hole (first through hole) 5 is formed so as to penetrate the electrode pad from the rear surface 3 of the semiconductor wafer 1 in the thickness direction and reduce the metallic bump 4 by irradiating a laser beam to the rear surface 3 of the semiconductor wafer 1. In this case, the metallic bump 4 functions as the stopper against the laser processing. Thereafter, as shown in FIG. 6(d), an epoxy-based insulating resin film is laminated on the rear surface 3 of the semiconductor wafer 1 so that an insulating resin 6 can be filled into the through hole 5 and cover the rear surface 3 of the semiconductor wafer 1.

Then, as shown in FIG. 6(e), a through hole (second through: hole) 7 is formed in the insulating resin 6 filled in the through hole 5 so as to penetrate the electrode pad 2a and reach the metallic bump 4 by means of laser processing or the like. The diameter of the through hole 7 is set smaller than the diameter of the through hole 5. In this way, the insulating resin 6 results in being formed on the inner silicon wall of the through hole 5. Then, as shown in FIG. 6(f), a conductor 8 is formed on the rear surface 3 of the semiconductor wafer 1 and the side wall, the bottom of the through hole 7 by means of electroless plating or the like. The conductor 8 is patterned, thereby forming an intended penetrating electrode 9 through the semiconductor wafer 1 in the thickness direction from the rear surface 3 to the main surface 2 of the semiconductor wafer 1. In this way, the intended penetrating electrode 9 is formed without high processing accuracy by using the metallic bump 4 as the stopper against the laser processing so that the penetrating electrode 9 can be effectively formed under good condition.

Although the present invention was described in detail with reference to the above examples, this invention is not limited to the above disclosure and every kind of variation and modification may be made without departing from the scope of the present invention.

What is claimed is:

1. A semiconductor device, comprising:
a semiconductor substrate with an electrode pad on a main surface of said semiconductor substrate;
a first penetrating electrode which includes a through hole formed through said semiconductor substrate in the thickness direction from a rear surface to said main surface in said semiconductor substrate so as to reach a metallic bump formed on said electrode pad, an insulating resin formed so as to fill said through hole in and a conductor formed in said through hole with insulated from said semiconductor substrate by said insulating resin and electrically to connect said electrode pad and said rear surface of said semiconductor wafer;
a semiconductor chip mounted on said rear surface of said semiconductor wafer so that a rear surface of said semiconductor chip is faced to said rear surface of said semiconductor wafer; and
a wiring to electrically connect said first penetrating electrode and an electrode formed on said semiconductor chip.

2. The semiconductor device as set forth in claim 1, further comprising:
an additional insulating resin formed so as to cover said semiconductor chip and said first penetrating electrode; and
a second penetrating electrode formed so as to penetrate said additional insulating resin and to be electrically connected with said an electrode formed on said semiconductor wafer.

3. The semiconductor device as set forth in claim 2, further comprising
a third penetrating electrode formed so as to penetrate said additional insulating resin and to be electrically connected with an electrode formed on said semiconductor chip.

4. A semiconductor device, comprising:
a semiconductor substrate with an electrode pad on a main surface of said semiconductor substrate; and
a penetrating electrode which includes a through hole formed through said semiconductor substrate in the thickness direction from a rear surface to said main surface in said semiconductor substrate so as to reach a metallic bump formed on said electrode pad, an insulating resin formed so as to fill said through hole in and a conductor formed in said through hole with insulated from said semiconductor substrate by said insulating resin and electrically to connect said electrode pad and said rear surface of said semiconductor wafer.

5. A method for fabricating a semiconductor device, comprising:
forming a first through hole at a semiconductor substrate with an electrode pad on a main surface of said semiconductor substrate through said semiconductor substrate in the thickness direction from a rear surface to said main surface of said semiconductor substrate so as to reach a metallic bump formed on said electrode pad;
filling an insulating resin into said first through hole from said rear surface of said semiconductor wafer;
forming a second through hole in said insulating resin from said rear surface of said semiconductor wafer so as to reach a metallic bump formed on said electrode pad under the condition that a diameter of said second through hole is set smaller than a diameter of said first through hole;
forming, in said second through hole, a first penetrating electrode made of a conductor which is formed over said rear surface of said semiconductor wafer so as to be electrically contacted with said electrode pad;
mounting a semiconductor chip on said rear surface of said semiconductor wafer so that a rear surface of said semiconductor chip is faced to said rear surface of said semiconductor wafer; and
forming a wiring to electrically connect said first penetrating electrode and an electrode formed on said semiconductor chip.

6. The fabricating method as set forth in claim 5,
wherein said first through hole is formed by means of laser processing under the condition that said metallic bump functions as a stopper against said laser processing.

7. The fabricating method as set forth in claim 6,
wherein a thickness of said metallic bump is set within 3 to 20 μm.

8. The fabricating method as set forth in claim 5, further comprising
washing a processed surface of said semiconductor wafer after said first through hole is formed.

9. The fabricating method as set forth in claim 6, further comprising:
forming a protective film on said rear surface of said semiconductor wafer before said first through hole is formed; and
removing said protective film after said first through hole is formed.

10. The fabricating method as set forth in claim 5,
wherein said insulating resin is filled in said first through hole by means of vacuum lamination or roll-coating.

11. The fabricating method as set forth in claim 5,
wherein said second through hole is formed by means of laser processing.

12. The fabricating method as set forth in claim 5,
wherein said forming of said wiring comprises:
forming an additional insulating resin so as to cover said semiconductor chip and said first penetrating electrode;
forming, in said additional insulating resin, a third through hole at a position commensurate with a wafer electrode formed on said semiconductor wafer; and
forming a second penetrating electrode so as to fill said third through hole and to be electrically connected with said wafer electrode.

13. The fabricating method as set forth in claim 12,
wherein said forming of said wiring further comprises:
forming, in said additional insulating resin, a fourth through hole at a position commensurate with a chip electrode formed on said semiconductor chip; and
forming a third penetrating electrode so as to fill said fourth through hole in and to be electrically connected with said chip electrode.

14. A method for fabricating a semiconductor device, comprising:
forming a first through hole at a semiconductor substrate with an electrode pad on a main surface of said semiconductor substrate through said semiconductor substrate in the thickness direction from a rear surface to said main surface of said semiconductor substrate so as to reach a metallic bump formed on said electrode pad;
filling an insulating resin into said through hole from said rear surface of said semiconductor wafer;
forming a second through hole in said insulating resin from said rear surface of said semiconductor wafer so as to reach a metallic bump formed on said electrode pad under the condition that a diameter of said second through hole is set smaller than a diameter of said first through hole; and
forming, in said second through hole, a penetrating electrode made of a conductor which is formed over said rear surface of said semiconductor wafer so as to be electrically, contacted with said electrode pad.

15. The fabricating method as set forth in claim 14,
wherein said first through hole is formed by means of laser processing under the condition that said metallic bump functions as a stopper against said laser processing.

16. The fabricating method as set forth in claim 15,
wherein a thickness of said metallic bump is set within 3 to 20 μm.

17. The fabricating method as set forth in claim 14, further comprising
washing a processed surface of said semiconductor wafer after said first through hole is formed.

18. The fabricating method as set forth in claim 14, further comprising:
forming a protective film on said rear surface of said semiconductor wafer before said first through hole is formed; and
removing said protective film after said first through hole is formed.

19. The fabricating method as set forth in claim 14,
wherein said insulating resin is filled in said first through hole by means of vacuum lamination or roll-coating.

20. The fabricating method as set forth in claim 14,
wherein said second through hole is formed by means of laser processing.
